(19) United States
(12) Patent Application Publication
(10) Pub. No.: US 2025/0079046 A1
(43) Pub. Date: Mar. 6, 2025

(54) COAXIAL CABLE AND SEMICONDUCTOR DEVICE TESTING APPARATUS

(71) Applicant: ADVANTEST Corporation, Tokyo (JP)

(72) Inventor: Wataru Saeki, Tokyo (JP)

(73) Assignee: ADVANTEST Corporation, Tokyo (JP)

(21) Appl. No.: 18/751,658

(22) Filed: Jun. 24, 2024

(30) Foreign Application Priority Data
Sep. 5, 2023 (JP) 2023-143892

(51) Int. Cl. H01B 11/18

(52) U.S. Cl. CPC H01B 11/18

(57) ABSTRACT

A coaxial cable includes an inner conductor including a central part and a conductive layer surrounding the central part, an insulator surrounding the inner conductor, and an outer conductor surrounding the insulator. The central part includes either a cavity or a portion made of resin material.

### CROSS-REFERENCE TO RELATED APPLICATIONS

The present application claims priority to Japanese Patent Application No. 2023-143892, filed Sep. 5, 2023. The contents of this application are incorporated herein by reference in their entirety.

### BACKGROUND

### Technical Field

The present invention relates to a coaxial cable and a semiconductor device testing apparatus including the coaxial cable.

### Discussion of the Background

As a semiconductor device testing apparatus for testing the electrical characteristics of various semiconductor devices (DUT) such as semiconductor integrated circuit elements, an apparatus includes a DSA with a socket, a test head with pin electronics, and a motherboard with a coaxial cable electrically connecting the DSA and the test head (refer to, for example, Patent Document 1).

### Patent Document

PATENT DOCUMENT 1: JP 2008-078048 A

Because the inner conductor of the coaxial cable described above is formed of a solid metal wire made of a metal material such as copper, the rigidity of the coaxial cable is relatively high. Further, in the semiconductor device testing apparatus, there may be cases where a wiring board and a coaxial cable are connected by using a connector and a plurality of coaxial cables are connected to one connector. In this case, because the reaction force from the coaxial cable becomes stronger as the number of coaxial cables is increased, a connection failure such as disconnection may occur due to forcibly pushing the coaxial cable or the like when assembling the motherboard.

Further, in order to absorb mechanical errors when fitting connectors, there may be cases where the connecters include a sliding function that allows one connector (the connector to which the coaxial cable is connected) to slide with respect to the other connector (the connector mounted on the wiring board) in a lateral direction (perpendicular to the fitting direction). When the number of coaxial cables connected to one connector is increased, the sliding function may not sufficiently function due to strong reaction force from the coaxial cables, and a connection failure may occur.

Furthermore, in the semiconductor device testing apparatus described above, the connector is inserted and removed every time the type of DUT is replaced. When a large number of coaxial cables connected to one connector is increased, because the connectors may be fitted together in an inclined state due to the strong reaction force from the coaxial cables, it may not be possible to ensure sufficient connection reliability in the insertion and removal of the connectors for several thousand times.

### SUMMARY

One or more embodiments provide a coaxial cable capable of reducing reaction force, and a semiconductor device testing apparatus including the coaxial cable.

An aspect 1 of one or more embodiments is a coaxial cable comprising: an inner conductor; an insulator surrounding the inner conductor; an outer conductor surrounding the insulator; wherein the inner conductor comprises: a central part comprising a portion made of a first resin material or a portion that is a cavity; and a first conductive layer made of a first conductive material and surrounding the central part.

An aspect 2 of one or more embodiments may be the coaxial cable of the aspect 1, wherein the first resin material may have a Young's modulus smaller than a Young's modulus of the first conductive material.

An aspect 3 of one or more embodiments may be the coaxial cable of the aspect 1 or 2, wherein the first resin material may have a thermal conductivity lower than a thermal conductivity of the first conductive material.

An aspect 4 of one or more embodiments may be the coaxial cable of any one of the aspects 1 to 3, wherein the first resin material may have a density lower than a density of the first conductive material.

An aspect 5 of one or more embodiments may be the coaxial cable of any one of the aspects 1 to 4, wherein the first conductive layer may include a first thin film or a first metal foil.

An aspect 6 of one or more embodiments may be the coaxial cable of any one of the aspects 1 to 5, wherein the first conductive layer may have a thickness of 20 μm or less.

An aspect 7 of one or more embodiments may be the coaxial cable of any one of the aspects 1 to 6, wherein the central part may comprise a base member made of the first resin material, and the first conductive layer may cover an outer peripheral surface of the base member.

An aspect 8 of one or more embodiments may be the coaxial cable of the aspect 7, wherein a ratio of a cross-sectional area of the base member to a cross-sectional area of the inner conductor may be 50% or more.

An aspect 9 of one or more embodiments may be the coaxial cable of the aspect 7 or 8, wherein the first conductive layer may include a first thin film or a first metal foil, and the first thin film may include a plating layer or a coating layer formed on the outer peripheral surface of the base member.

An aspect 10 of one or more embodiments may be the coaxial cable of any one of the aspects 1 to 6, wherein the central part may comprise the cavity, and the first conductive layer may cover an inner peripheral surface of the insulator.

An aspect 11 of one or more embodiments may be the coaxial cable of the aspect 10, wherein a ratio of a cross-sectional area of the cavity to a cross-sectional area of the inner conductor may be 50% or more.

An aspect 12 of one or more embodiments may be the coaxial cable of the aspect 10 or 11, wherein the first conductive layer may include a first thin film or a first metal foil, and the first thin film may include a plating layer or a coating layer formed on the inner peripheral surface of the insulator.

An aspect 13 of one or more embodiments may be the coaxial cable of any one of the aspects 1 to 6, wherein the central part may comprise a wire assembly comprising a resin wire made of the first resin material, the first conductive layer may cover an outer peripheral surface of the wire assembly.

An aspect 14 of one or more embodiments may be the coaxial cable of the aspect 13, wherein a ratio of a cross-sectional area of the resin wires to a cross-sectional area of the inner conductor may be 50% or more.

An aspect 15 of one or more embodiments may be the coaxial cable of the aspect 13 or 14, wherein the first conductive layer may include a first thin film or a first metal foil, and the first thin film may include a plating layer or a coating layer formed on the outer peripheral surface of the wire assembly.

An aspect 16 of one or more embodiments may be the coaxial cable of any one of the aspects 13 to 15, wherein the wire assembly may comprise a first conductive wire made of a second conductive material.

An aspect 17 of one or more embodiments is a coaxial cable comprising: an inner conductor; an insulator surrounding the inner conductor; and an outer conductor surrounding the insulator; wherein the inner conductor comprises a wire assembly comprising wires, and the wires include: an inner wire comprising a portion made of a second resin material; and outer wires comprising portions made of a third conductive material and arranged to surround the inner wire.

An aspect 18 of one or more embodiments may be the coaxial cable of the aspect 17, wherein the second resin material may have a Young's modulus smaller than a Young's modulus of the third conductive material.

An aspect 19 of one or more embodiments may be the coaxial cable of the aspect 17 or 18, wherein the second resin material may have a thermal conductivity lower than a thermal conductivity of the third conductive material.

An aspect 20 of one or more embodiments may be the coaxial cable of any one of the aspects 17 to 19, wherein the second resin material may have a density lower than a density of the third conductive material.

An aspect 21 of one or more embodiments may be the coaxial cable of any one of the aspects 17 to 20, wherein an outer wire including in the outer wires may comprise: a first resin body made of a third resin material; and a second conductive layer made of the third conductive material and covering an outer peripheral surface of the first resin body.

An aspect 22 of one or more embodiments may be the coaxial cable of the aspect 21, wherein the third resin material may have a Young's modulus smaller than a Young's modulus of the third conductive material.

An aspect 23 of one or more embodiments may be the coaxial cable of the aspect 21 or 22, wherein the third resin material may have a thermal conductivity lower than a thermal conductivity of the third conductive material.

An aspect 24 of one or more embodiments may be the coaxial cable of any one of the aspects 21 to 23, wherein the third resin material may have a density lower than a density of the third conductive material.

An aspect 25 of one or more embodiments may be the coaxial cable of any one of the aspects 21 to 24, wherein the second conductive layer may include a second thin film or a second metal foil.

An aspect 26 of one or more embodiments may be the coaxial cable of any one of the aspects 21 to 25, wherein the second conductive layer may have a thickness of 20 μm or less.

An aspect 27 of one or more embodiments may be the coaxial cable of any one of the aspects 21 to 26, wherein the second conductive layer may include a second thin film, and the second thin film may include a plating layer or a coating layer formed on the outer peripheral surface of the first resin body.

An aspect 28 of one or more embodiments may be the coaxial cable of any one of the aspects 17 to 20, wherein the outer wires may include a second conductive wire made of the third conductive material.

An aspect 29 of one or more embodiments may be the coaxial cable of any one of the aspects 1 to 28, wherein the outer conductor may comprise a braided shield comprising coated wires that are braided, a coated wire included in the coated wires may comprise: a second resin body made of a fourth resin material; and a third conductive layer (an additional conductive layer) made of a fourth conductive material and covering an outer peripheral surface of the second resin body.

An aspect 30 of one or more embodiments may be the coaxial cable of the aspect 29, wherein the fourth resin material may have a Young's modulus smaller than a Young's modulus of the fourth conductive material.

An aspect 31 of one or more embodiments may be the coaxial cable of the aspect 29 or 30, wherein the fourth resin material may have a thermal conductivity lower than a thermal conductivity of the fourth conductive material.

An aspect 32 of one or more embodiments may be the coaxial cable of any one of the aspects 29 to 31, wherein the fourth resin material may have a density lower than a density of the fourth conductive material.

An aspect 33 of one or more embodiments may be the coaxial cable of any one of the aspects 29 to 32, wherein the third conductive layer may include a third thin film or a third metal foil.

An aspect 34 of one or more embodiments may be the coaxial cable of any one of the aspects 29 to 33, wherein the third conductive layer may have a thickness of 20 μm or less.

An aspect 35 of one or more embodiments may be the coaxial cable of any one of the aspects 29 to 34, wherein the third conductive layer may include a third thin film, and the third thin film may include a plating layer or a coating layer formed on the outer peripheral surface of the second resin body.

An aspect 36 of one or more embodiments may be the coaxial cable of any one of the aspects 1 to 35, wherein the outer conductor may comprise a fourth conductive layer (an additional conductive layer) covering an outer peripheral surface of the insulator.

An aspect 37 of one or more embodiments may be the coaxial cable of the aspect 36, wherein the fourth conductive layer may include a fourth thin film or a fourth metal foil.

An aspect 38 of one or more embodiments may be the coaxial cable of the aspect 37, wherein the fourth thin film may include a fourth plating layer or a fourth coating layer formed on the outer peripheral surface of the insulator.

An aspect 39 of one or more embodiments may be the coaxial cable of any one of the aspects 1 to 38, wherein the coaxial cable may be used in semiconductor device testing apparatus that tests a semiconductor device.

An aspect 40 of one or more embodiments is a semiconductor device testing apparatus that tests a semiconductor device, comprising the coaxial cable of any one of claims 1 to 39.

An aspect 41 of one or more embodiments may be the semiconductor device testing apparatus of the aspect 40, the semiconductor device testing apparatus may comprise: a first connector connected to an end of the coaxial cable; and a second connector fitted to the first connector and mounted on a wiring board.

According to one or more embodiments, because the inner conductor comprises a central part comprising a portion made of a first resin material or a portion that is a cavity and a first conductive layer made of a first conductive material and surrounding the central part, it is possible to reduce reaction force of the coaxial cable.

According to one or more embodiments, because the inner conductor comprises a wire assembly comprising wires and the wires include an inner wire comprising a portion made of a second resin material and outer wires comprising portions made of a third conductive material and surrounding the inner wire, it is possible to reduce reaction force of the coaxial cable.

### BRIEF DESCRIPTION OF THE DRAWINGS

FIG. 1 is a schematic cross-sectional view showing an overall configuration of a semiconductor device testing apparatus in a first example of one or more embodiments.

FIG. 2 is an exploded sectional view showing a DSA and a motherboard in the first example and a view corresponding to the section II in FIG. 1.

FIG. 3 is a sectional view showing a coaxial cable in the first example.

FIG. 4 is a sectional view showing a coaxial cable in a second example of one or more embodiments.

FIG. 5 is a sectional view showing a coaxial cable in a third example of one or more embodiments.

FIG. 6 is a sectional view showing a modification of the coaxial cable in the third example.

FIG. 7 is a sectional view showing a coaxial cable in a fourth example of one or more embodiments.

FIG. 8 is a sectional view showing a modification of the coaxial cable in the fourth example.

FIG. 9 is a sectional view showing a coaxial cable in a fifth example of one or more embodiments.

FIG. 10 is an enlarged view of the section X in FIG. 9.

FIG. 11 is an enlarged sectional view showing a modification of the coaxial cable in the fifth example.

### DESCRIPTION OF THE EMBODIMENTS

Hereinafter, embodiments will be described with reference to the drawings.

### First Example

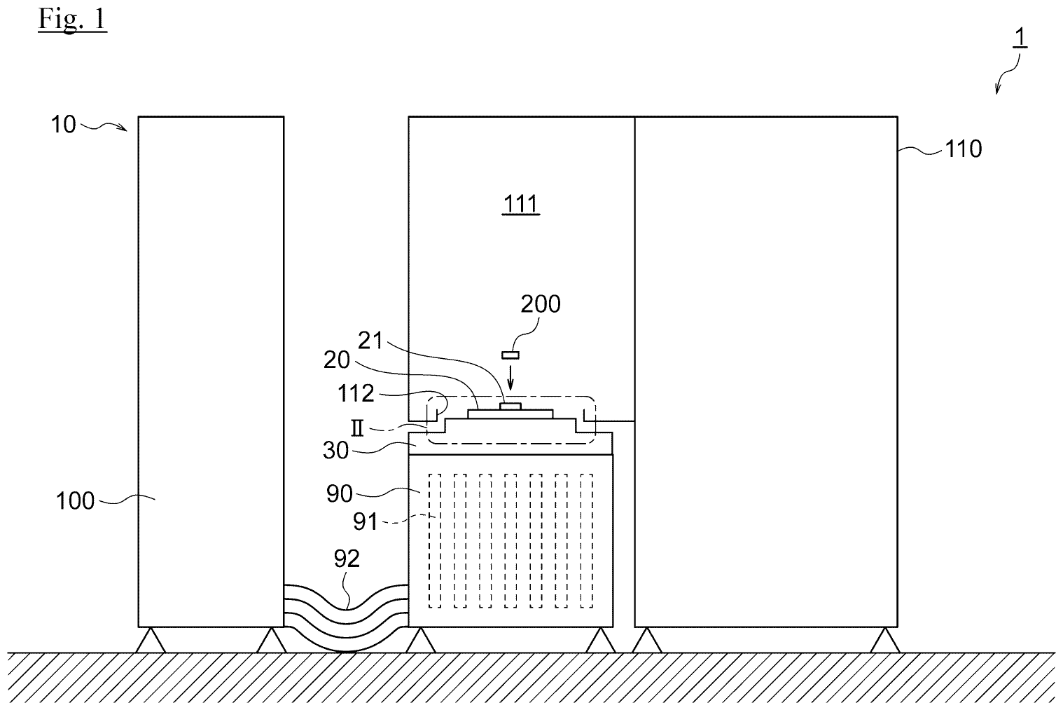

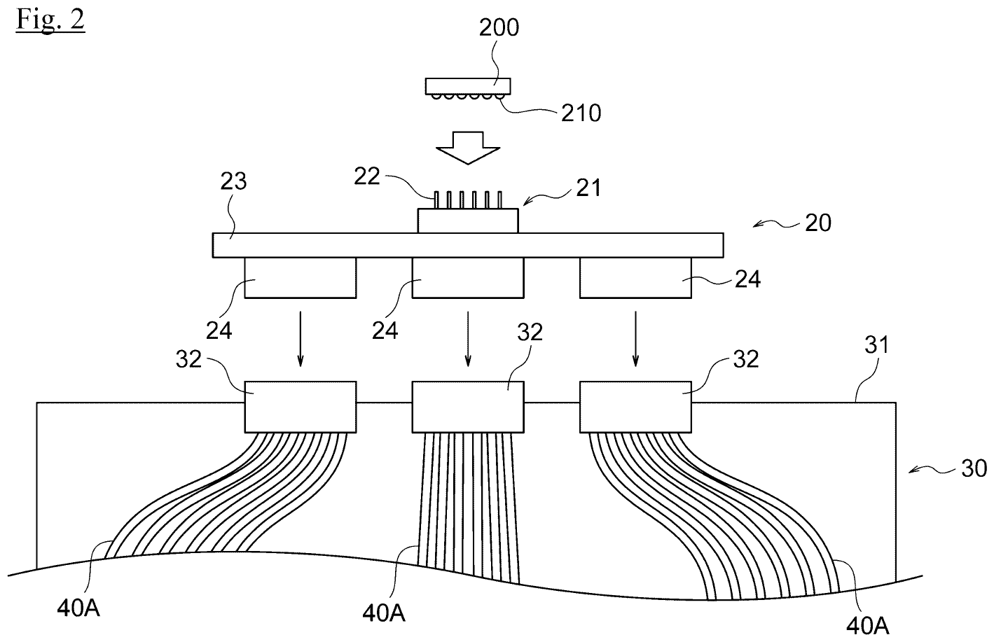

FIG. 1 is a schematic cross-sectional view showing the overall configuration of the semiconductor device testing apparatus 1 in a first example of one or more embodiments, and FIG. 2 is an exploded sectional view showing the DSA 20 and motherboard 30 in the first example and a view corresponding to the section II in FIG. 1.

The semiconductor device testing apparatus 1 in the present example is an apparatus that tests the electrical characteristics and the like of a semiconductor device (hereinafter also simply referred to as “DUT”) 200 such as a semiconductor integrated circuit element. Although not particularly limited, a memory device, a logic device, and SoC (System on chip) can be exemplified as a specific example of the DUT 200 to be tested. As shown in FIG. 1, the semiconductor device testing apparatus 1 includes a tester 10 that tests the DUT 200, and a handler 110 that handles the DUT 200 and presses the DUT 200 against a socket 21. The tester 10 includes a DSA20, a motherboard 30, a test head 90, and a main frame 100. The configuration of the tester 10 is not particularly limited to the following as long as it includes the coaxial cable 40A.

As shown in FIG. 1 and FIG. 2, the DSA (Device Specific Adapter) 20 includes a socket 21, a socket board 23, and a plurality of connectors 24. The DSA 20 is electrically connected to the test head 90 via the motherboard 30. The DSA 20 is detachable from the motherboard 30. The DSA 20 is designed according to the type of the DUT 200, and the DSA 20 is replaced with one corresponding to the type when changing the type of DUT 200. The number of DSAs 20 mounted on the motherboard 30 is not particularly limited, and a plurality of DSAs 20 may be mounted on the motherboard 30.

When testing the DUT 200, the DUT 200 is pressed against the socket 21 by the handler 110, therefore the DUT 200 and the socket 21 are electrically connected. The socket 21 includes a plurality of contactors 22 that respectively contact terminals 210 of the DUT 200. Although not particularly limited, a pogo pin, a vertical-type probe needle, a cantilever-type probe needle, an anisotropic conductive rubber sheet, a bump provided on a membrane, or a contactor manufactured using MEMS technology can be exemplified as a specific example of the contactor 22.

The socket board 23 is a wiring board with the above-described socket 21 mounted on its upper surface. The number of sockets 21 mounted on the socket board 23 is not particularly limited, and a plurality of sockets 21 may be mounted on the socket board 23. Further, although not particularly shown, a socket guide for positioning the DUT 200 with respect to the socket 21 may be attached to the upper surface of the socket board 23. The coaxial connector 24 is mounted on the lower surface of the socket board 23. The socket 21 and the coaxial connector 24 are electrically connected via a conductive path (not shown) such as a wiring pattern and a through hole formed in the socket board 23.

The motherboard 30 is a relaying device that electrically connects the DSA 20 and the test head 90. The motherboard 30 includes a housing 31, a plurality of coaxial connectors 32, and a plurality of coaxial cables 40A. Although not particularly limited, for example, the motherboard 30 includes 100 or more coaxial connectors 32, and 50 to 100 coaxial cables 40A are connected to one coaxial connector 32, and as a result, the motherboard 30 includes several thousand to tens of thousands of coaxial cables 40A. The coaxial connector 32 is connected to one end (the upper end in FIG. 2) of the coaxial cable 40A. The coaxial connector 32 can be fitted into the coaxial connector 24 of the DSA 20 described above. The coaxial connector 32 is held by the upper part of the housing 31 to correspond to the coaxial connector 24 of the DSA 20. When the DSA 20 is attached to the motherboard 30, the coaxial connector 24 of the DSA 20 and the coaxial connector 32 of the motherboard 30 are fitted together. The configuration of the coaxial cable 40A will be described in detail later.

As shown in FIG. 1, the test head 90 accommodates therein a test module (pin electronics card) 91 for testing the DUT 200. The test module 91 is electrically connected to the coaxial cable 40A of the motherboard 30 via a coaxial connector (not shown) or the like connected to the other end of the coaxial cable 40A. The test module 91 tests the DUT 200 by transmitting and receiving test signals to and from the DUT 200 via the DSA 20 and the motherboard 30. The test head 90 is connected to the main frame 100 via a cable 92.

The main frame (tester main body) 100 is, for example, a computer that executes a program, and the main frame 100 communicates with the test modules 91 in the test head 90 according to the program to control the test modules 91. Each of the test module 91 generates test signals according to instructions from the main frame 100 and outputs the test signals to the DUT 200.

Although not particularly illustrated, the handler 110 includes, for example, a transport device that transports the test tray on which the DUT 200 is mounted above the DSA 20, a pressing device that presses the DUT 200 against the socket 21 of the DSA 20, and a sorting device that sorts the DUT 200 according to the test result while taking the DUT 200 out from the test tray. The handler 110 also includes a chamber 111 as a temperature adjusting device that applies high or low temperature thermal stress to the DUT 200. The chamber 111 includes a thermostatic chamber capable of maintaining the temperature in the chamber at a desired temperature. Therefore, the semiconductor device testing apparatus 1 is capable of testing the DUT 200 while applying thermal stress to the DUT 200, and a so-called high-temperature test and a low-temperature test can be performed.

The DSA 20 enters the chamber 111 through an opening 112 formed in the handler 110, and the socket 21 of the DSA 20 is disposed in the chamber 111. The DUT 200 and the socket 21 are electrically connected by pressing the DUT 200 against the socket 21 of the DSA 20 by the pressing device of the handler 110.

The handler 110 may be of a type where the handler 110 includes a contact arm that suction-holds and moves the DUT 200 without using a test tray and the contact arm presses the DUT 200. In this case, the handler 110 may include a heater or a heat sink provided in the front end of the contact arm as a temperature adjusting device instead of the chamber 111. Alternatively, the handler 110 may include, in addition to the chamber 111, a heater or a heat sink provided in the front end of the contact arm as a temperature adjusting device.

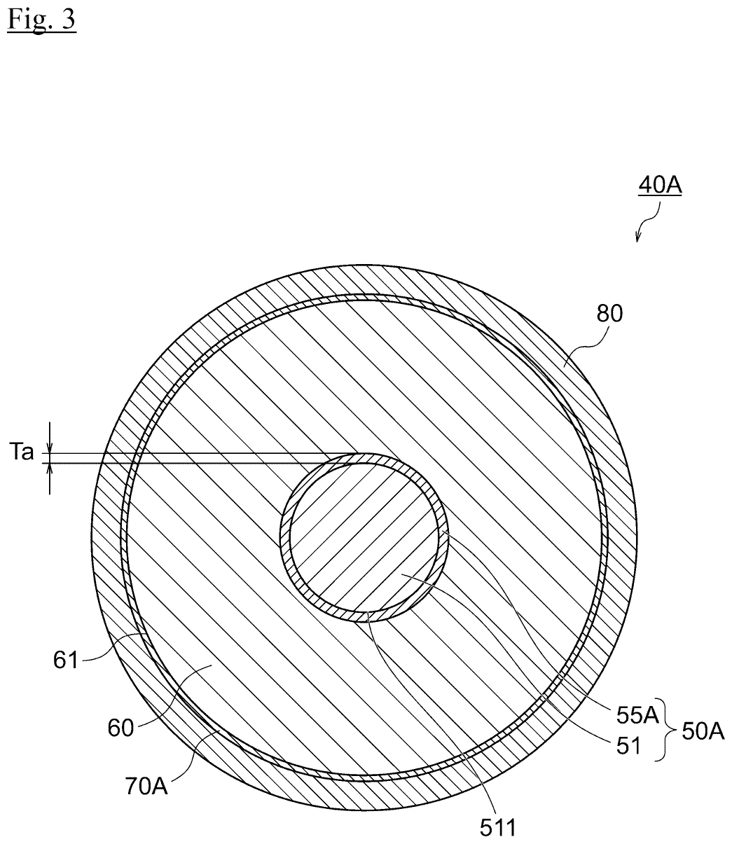

Next, the configuration of the coaxial cable 40A included in the motherboard 30 described above will be described in detail with reference to FIG. 3. FIG. 3 is a sectional view showing the coaxial cable 40A in the first example.

As shown in FIG. 3, the coaxial cable 40A in the present example includes an inner conductor 50A, an insulator 60 surrounding the inner conductor 50A, an outer conductor (a conducting layer) 70A surrounding the insulator 60, and a jacket 80 surrounding the outer conductor 70A. The coaxial cable 40A is a cable extending in the normal direction of the paper surface of FIG. 3, and FIG. 3 shows a cross section perpendicular to the longitudinal direction (axial direction) of the coaxial cable 40A.

The inner conductor 50A functions as a transmission path for transmitting electrical signals between the test head 90 and the DUT 200. On the other hand, the outer conductor 70A is connected to the ground and functions as an electromagnetic shield layer for shielding noises. In the semiconductor device testing apparatus 1 described above, the electrical signal flowing through the inner conductor 50A is a high frequency electrical signal and is an electrical signal with a frequency of 10 MHz or more, an electrical signal with a frequency of 1 GHz or more, or an electrical signal with a frequency of 10 GHz or more.

The inner conductor 50A includes a base member 51 and a first conductive layer 55A. The base member 51 is a single linear member extending in the axial direction of the coaxial cable 40A. The base member 51 has a circular cross-sectional shape and is a solid linear member made of a first resin material. The base member 51 is a linear member made of only the first resin material. On the other hand, the first conductive layer 55A is made of a first metal material and covers the entire outer peripheral surface 511 of the base member 51. The first conductive layer 55A covers the outer circumferential surface 511 of the base member 51 over the entire area in the axial direction of the coaxial cable 40A.

The ratio Ra (Ra=Sb/Sa×100) of the cross-sectional area Sb of the base member 51 to the cross-sectional area Sa of the inner conductor 50A is preferably 50% or more and 99.9% or less (50%≤Ra≤99.9%), more preferably 75% or more and 99.9% or less (75%≤Ra≤99.9%). Thus, it is possible to further reduce the rigidity of the coaxial cable 40A.

The first conductive layer 55A is a thin film formed on the outer peripheral surface 511 of the base member 51. The thin film is, for example, a plated layer formed by a plating method such as electrolytic plating or electroless plating. Although not particularly limited, the thickness Ta of the thin film is, for example, preferably 0.1 μm or more and 20 μm or less (0.1 μm≤Ta≤20 μm), and more preferably 0.1 μm or more and 10 μm or less (0.1 μm≤Ta≤10 μm). Thus, it is possible to further reduce the rigidity of the coaxial cable 40A. The thickness Ta of the thin film can be set according to the frequency of the electric signal flowing through the coaxial cable 40A. Specifically, when the frequency of the electrical signal is high, the thickness Ta of the first conductive layer 55A is set to be thin, and when the frequency of the electric signal is low, the thickness Ta of the first conductive layer 55A is set to be thick.

The method of forming the thin film of the first conductive layer 55A is not limited to the above-described plating method, and the first conductive layer 55A may be formed by, for example, physical vapor deposition method (PVD) such as vacuum deposition or sputtering, or chemical vapor deposition method (CVD). Alternatively, the thin film of the first conductive layer 55A may be a coating layer. Although not particularly limited, the coating layer can be formed, for example, by applying a coating material containing metal particles and an adhesive to the outer peripheral surface 511 of the base member 51 and curing it by heating.

Alternatively, the first conductive layer 55A may be formed of a metal foil instead of the thin film described above. In this case, the first conductive layer 55A is formed by wrapping the metal foil around the outer peripheral surface 511 of the base member 51. Although not particularly limited, a copper foil and a silver-plated copper foil can be exemplified as a specific example of the metal foil constituting the first conductive layer 55A.

Under the same measurement conditions, the first resin material of which the base member 51 is made has the Young's modulus (Era) smaller than the Young's modulus (Ema) of the first metal material of which the first conductive layer 55A is made (Era<Ema). Further, under the same measurement conditions, the first resin material has the thermal conductivity (λra) lower than the thermal conductivity (λma) of the first metal material of which the first conductive layer 55A is made (λra<λma). Furthermore, under the same measurement conditions, the first resin material has the density (ρra) lower than the density (mass per unit volume) (ρma) of the first metal material of which the first conductive layer 55A is made (ρra<ρma).

Although a specific example of the first resin material of which the base material 51 is made is not particularly limited as long as it is a resin material having an electrically insulation property, for example, imide-based resin such as polyimide, fluororesin such as polytetrafluoroethylene (PTFE) and perfluoroalkoxy alkane (PFA), polyetheretherketone (PEEK), polyethylene (PE), and crosslinked foamed polyethylene can be exemplified. On the other hand, a specific example of the first metal material of which the first conductive layer 55A is made is not particularly limited as long as it is a metal material having good conductivity, but for example, silver, copper, or alloys thereof can be exemplified.

The insulator 60 is a dielectric interposed between the inner conductor 50A and the outer conductor 70A. The insulator 60 has an annular cross-sectional shape and covers the entire outer peripheral surface of the inner conductor 50A. Further, the insulator 60 covers the outer circumferential surface of the inner conductor 50A over the entire area in the axial direction of the coaxial cable 40A.

The insulator 60 is made of a resin material having an electrically insulation property. Although not particularly limited, for example, imide-based resin such as polyimide, fluororesin such as polytetrafluoroethylene (PTFE), polyethylene (PE), and crosslinked foamed polyethylene can be exemplified as a specific example of a material of which the insulator 60 is made. As a material of which the insulator 60 is made, the same resin material as the first resin material of which the base member 51 described above is made may be used.

The outer conductor 70A covers the outer peripheral surface of the insulator 60. The outer conductor 70A has an annular cross-sectional shape and covers the entire outer peripheral surface of the insulator 60. The outer conductor 70A is arranged concentrically with the inner conductor 50A, and the distance between the inner conductor 50A and the outer conductor 70A is defined by the insulator 60. The outer conductor 70A covers the outer circumferential surface of the inner conductor 50A over the entire area in the axial direction of the coaxial cable 40A.

The outer conductor 70A is a thin film formed on the outer peripheral surface 61 of the insulator 60. The thin film is made of a metal material. The thin film is, for example, a plated layer formed by a plating method such as electrolytic plating or electroless plating. Although a specific example of the metal material of which the outer conductor 70A is made is not particularly limited as long as it has good conductivity, for example, silver, copper, or alloys thereof can be exemplified.

The method of forming the thin film of the outer conductor 70A is not limited to the above-described plating method, and the outer conductor 70A may be formed by, for example, physical vapor deposition method (PVD) or chemical vapor deposition method (CVD). Alternatively, the thin film of the outer conductor 70A may be a coating layer. Although not particularly limited, the coating layer can be formed, for example, by applying a coating material containing metal particles and an adhesive to the outer peripheral surface 61 of the insulator 60 and curing it by heating.

Alternatively, the outer conductor 70A may be formed of a metal foil instead of the thin film described above. In this case, the outer conductor 70A is formed by wrapping the metal foil around the outer peripheral surface 61 of the insulator 60. Although not particularly limited, for example, a copper foil and a silver-plated copper foil can be exemplified as a specific example of the metal foil constituting the outer conductor 70A. Alternatively, instead of the thin film described above, a metal pipe such as a copper pipe may be used as the outer conductor 70A.

The jacket 80 convers the outer peripheral surface of the outer conductor 70A. The jacket 80 has an annular cross-sectional shape and covers the entire outer peripheral surface of the outer conductor 70A. Further, the jacket 80 covers the outer circumferential surface of the outer conductor 70A over the entire area in the axial direction of the coaxial cable 40A.

The jacket 80 is made of a resin material having an electrically insulation property. Although not particularly limited, for example, polyvinyl chloride (PVC), polyethylene (PE), polytetrafluoroethylene (PTFE), perfluoroalkoxy alkane (PFA), and fluorinated ethylene propylene (FEP) can be exemplified as a specific example of a resin material of which the jacket 80 is made.

Here, as described above, the reaction force from the coaxial cable becomes stronger as the number of coaxial cables connected to one connector is increased. Therefore, when assembling the motherboard, the coaxial cable itself may break or cracks may occur at the soldered joint between the inner conductor of the coaxial cable and the terminal of the coaxial connector due to forcibly pushing the coaxial cable or the like, and a connection failure may occur.

On the other hand, in the present example, because the inner conductor 50A includes the base member 51 made of the first resin material and the first conductive layer 55A surrounding the base member 51, it is possible to reduce the rigidity of the coaxial cable 40A and it is possible to reduce reaction force of the coaxial cable 40A. That is, in the present example, focusing on the fact that the frequency of the electric signals used in the semiconductor device testing device is high frequency and the electrical signals concentrate on the surface part of the conductor as the frequency of the electric signals is higher due to the skin effect, the surface part of the inner conductor is made of the first conductive material, and the inner part of the inner conductor is made of the first resin material, thus the reaction force of the coaxial cable 40A is reduced. Accordingly, it is possible to suppress the occurrence of disconnection when assembling the motherboard 30.

In the present example, because the reaction force of the coaxial cable 40A can be reduced as described above, even when the connector 32 to which the coaxial cable 40A is connected has the above-mentioned sliding function, it is possible to ensure sufficient contact pressure between the terminals of the connectors 32 and 24, and it is possible to suppress the occurrence of connection failures between the connectors 32 and 24.

In the present example, because the reaction force of the coaxial cable 40A can be reduced as described above, it is possible to suppress the occurrence of fitting of the connector 32 in an inclined state with respect to the counterpart connector 24, and it is possible to ensure sufficient connection reliability in the insertion and removal of the connectors 32 and 24 for several thousand times.

When performing a low-temperature test (for example, a test of the DUT at −50° C. to −40° C.) in the semiconductor device testing apparatus, if the inner conductor of the coaxial cable is a solid metal wire, heat may be transferred into the motherboard through the inner conductor, the inside of the motherboard may be cooled and dew condensation may occur. On the other hand, in the present example, because the inner conductor 50A includes the base member 51 made of the first resin material and the first conductive layer 55A surrounding the base member 51, it is possible to suppress heat transfer from the chamber 111 of the handler 110 to the inside of the motherboard 30 and it is possible to suppress formation of dew condensation inside the motherboard 30.

In the present example, because the inner conductor 50A includes the base member 51 made of the first resin material and the first conductive layer 55A surrounding the base member 51, it is possible to reduce the weight of several thousand to tens of thousands of coaxial cables 40A. Thus, it is possible to reduce the strength of the housing 31 holding the coaxial cable 40A, and it is possible to reduce the cost of the motherboard 30.

### Second Example

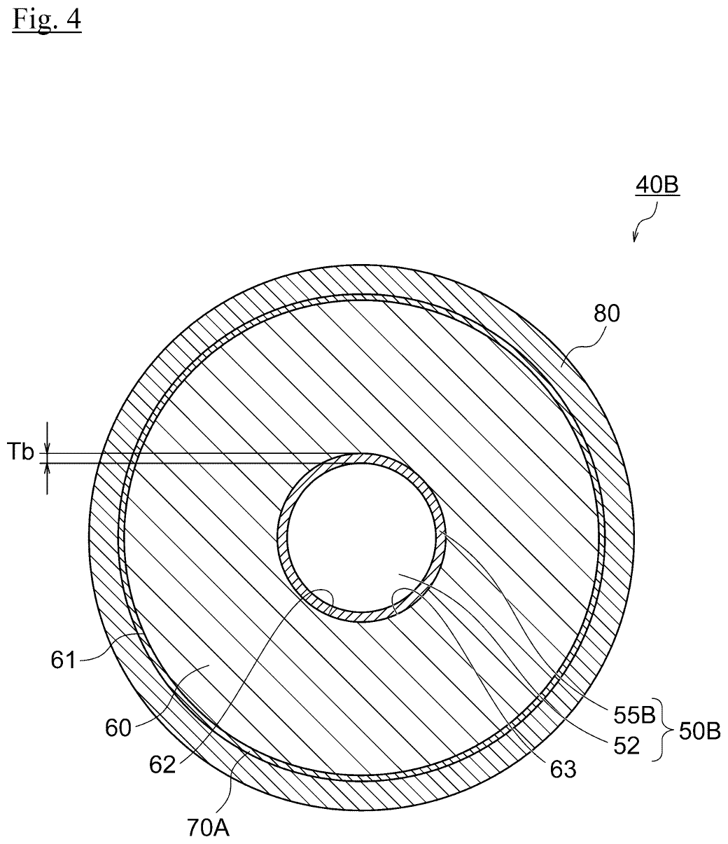

FIG. 4 is a sectional view showing the coaxial cable 40B in a second example of one or more embodiments. The present example is different from the first example in the configuration of the inner conductor 50B, but other configurations are the same as those of the first example. Hereinafter, the coaxial cable 40B in the second example will be described only with respect to differences from the first example, parts having the same configuration as those in the first example are denoted by the same reference numerals, and description thereof will be omitted.

As shown in FIG. 4, the inner conductor 50B in the present example includes a cavity 52 and a first conductive layer 55B. The cavity 52 is a space filled with gas such as air and exists in the inner hole 62 of the cylindrical insulator 60. The cavity 52 may be a vacuum space. The inner hole 62 has a circular cross-sectional shape and penetrates the insulator 60 over the entire axial direction of the coaxial cable 40B. That is, the insulator 60 is a cylindrical member and a hollow member.

The first conductive layer 55B is a thin film formed on the inner peripheral surface 63 of the inner hole 62 of the insulator 60. The first conductive layer 55B covers the entire circumference of the inner peripheral surface 63 of the inner hole 62. The first conductive layer 55B covers the inner circumferential surface 63 of the inner hole 62 over the entire area in the axial direction of the coaxial cable 40B. The cavity 52 is defined by the first conductive layer 55B formed on the inner peripheral surface 63 of the inner hole 62 of the insulator 60.

The ratio Rb (Rb=Sd/Sc×100) of the cross-sectional area Sd of the cavity 52 to the cross-sectional area Sc of the inner conductor 50B is preferably 50% or more and 99.9% or less (50%≤Rb≤99.9%), more preferably 75% or more and 99.9% or less (75%≤Rb≤99.9%). Thus, it is possible to further reduce the rigidity of the coaxial cable 40B.

Similar to the first conductive layer 55A of the first example, the first conductive layer 55B is made of the first metal material and is a plated layer formed by a plating method. Although a specific example of the first metal material is not particularly limited as long as it is a metal material having good conductivity, for example, silver, copper, or alloys thereof can be exemplified. Although not particularly limited, the thickness Tb of the thin film is, for example, preferably 0.1 μm or more and 20 μm or less (0.1 μm≤Tb≤20 μm), and more preferably 0.1 μm or more and 10 μm or less (0.1 μm≤Tb≤10 μm). Thus, it is possible to further reduce the rigidity of the coaxial cable 40B.

The first conductive layer 55B may be a thin film formed by a method other than plating such as physical vapor deposition (PVD) or chemical vapor deposition (CVD). Alternatively, the first conductive layer 55B may be a coating layer formed by applying a paint containing metal particles. Alternatively, the first conductive layer 55B may be formed of a metal foil instead of a thin film.

In the present example, because the inner conductor 50B includes the cavity 52 and the first conductive layer 55B surrounding the cavity 52, it is possible to reduce the rigidity of the coaxial cable 40B and it is possible to reduce reaction force of the coaxial cable 40B. That is, in the present example, focusing on the fact that the frequency of the electric signals used in the semiconductor device testing device is high frequency and the electrical signals concentrate on the surface part of the conductor as the frequency of the electric signals is higher due to the skin effect, the surface part of the inner conductor is made of the first conductive material, and the inner part of the inner conductor is the cavity, thus the reaction force of the coaxial cable 40B is reduced. Accordingly, it is possible to suppress the occurrence of disconnection when assembling the motherboard 30.

In the present example, because the reaction force of the coaxial cable 40B can be reduced as described above, similar to the first example, it is possible to suppress the occurrence of connection failures between the connectors 32 and 24, and it is possible to ensure sufficient connection reliability in the insertion and removal of the connectors 32 and 24 for several thousand times.

In the present example, because the inner conductor 50A includes the cavity 52, it is possible to suppress heat transfer from the chamber 111 of the handler 110 to the inside of the motherboard 30 and it is possible to suppress formation of dew condensation inside the motherboard 30.

In the present example, because the inner conductor 50A includes the cavity 52, it is possible to reduce the weight of several thousand to tens of thousands of coaxial cables 40B. Thus, it is possible to reduce the strength of the housing 31 holding the coaxial cable 40B, and it is possible to reduce the cost of the motherboard 30.

### Third Example

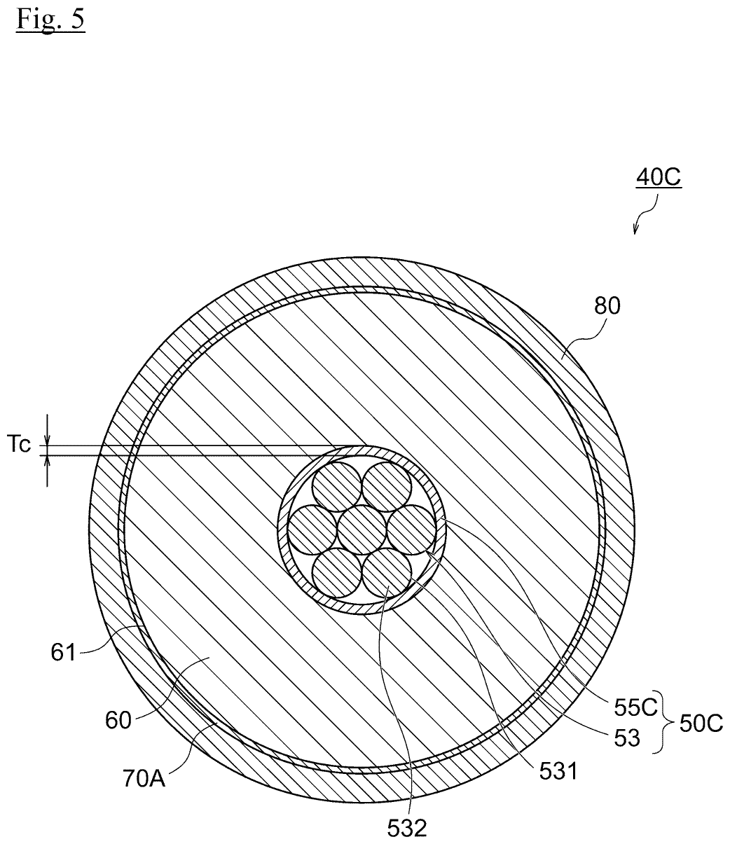

FIG. 5 is a sectional view showing the coaxial cable 40C in a third example of one or more embodiments. The present example is different from the first example in the configuration of the inner conductor 50C, but other configurations are the same as those of the first example. Hereinafter, the coaxial cable 40C in the third example will be described only with respect to differences from the first example, parts having the same configuration as those in the first example are denoted by the same reference numerals, and description thereof will be omitted.

As shown in FIG. 5, the inner conductor 50C of the present example includes a wire assembly 53 and a first conductive layer 55C. The wire assembly 53 includes a plurality of resin wires 532. Each of the resin wires 532 has a circular cross-sectional shape and is a solid linear member made of the first resin material. Each of the resin wires 532 is a linear member made of only the first resin material. The wire assembly 53 is a twisted wire formed by twisting the plurality of resin wires 532 together. The wire assembly 53 extends in the axial direction of the coaxial cable 40C.

The first conductive layer 55C is formed of a metal foil that covers the outer peripheral surface 531 of the wire assembly 53. Although not particularly limited, for example, a copper foil and a silver-plated copper foil can be exemplified as a specific example of the metal foil constituting the first conductive layer 55C. This first conductive layer 55C covers the entire circumference of the outer peripheral surface 531 of the wire assembly 53. The first conductive layer 55C covers the outer circumferential surface 531 of the wire assembly 53 over the entire area in the axial direction of the coaxial cable 40C.

The ratio Rc (Rc=Sf/Se×100) of the cross-sectional area Sf of the wire assembly 53 to the cross-sectional area Se of the inner conductor 50C is preferably 50% or more and 99.9% or less (50%≤Rc≤99.9%), more preferably 75% or more and 99.9% or less (75%≤Rc≤99.9%). Thus, it is possible to further reduce the rigidity of the coaxial cable 40C.

The first conductive layer 55C is formed of a metal foil made of the first metal material. Although not particularly limited, the thickness Tc of the thin film is, for example, preferably 0.1 μm or more and 20 μm or less (0.1 μm≤Tc≤20 μm), and more preferably 0.1 μm or more and 10 μm or less (0.1 μm≤Tc≤10 μm). Thus, it is possible to further reduce the rigidity of the coaxial cable 40C.

The first conductive layer 55C may be a thin film (plated layer) formed on the outer peripheral surface 531 of the wire assembly 53 by a plating method such as electrolytic plating or electroless plating. Alternatively, the first conductive layer 55 C may be a thin film formed by a method other than plating, such as physical vapor deposition (PVD) or chemical vapor deposition (CVD). Alternatively, the first conductive layer 55C may be a coating layer formed by applying a paint containing metal particles.

Under the same measurement conditions, the first resin material of which the resin wire 532 is made has the Young's modulus (Era) smaller than the Young's modulus (Ema) of the first metal material of which the first conductive layer 55C is made (Era<Ema). Further, under the same measurement conditions, the first resin material has the thermal conductivity (λra) lower than the thermal conductivity (λma) of the first metal material of which the first conductive layer 55C is made (λra<λma). Furthermore, under the same measurement conditions, the first resin material has the density (ρra) lower than the density (ρma) of the first metal material of which the first conductive layer 55C is made (ρra<ρma).

Although a specific example of the first resin material of which the resin wire 532 is made are not particularly limited as long as it is a resin material having an electrically insulation property, for example, imide-based resin such as polyimide, fluororesin such as polytetrafluoroethylene (PTFE), polyetheretherketone (PEEK), polyethylene (PE), and crosslinked foamed polyethylene can be exemplified. On the other hand, although a specific example of the first metal material of which the first conductive layer 55C is made is not particularly limited as long as it is a metal material having good conductivity, for example, silver, copper, or alloys thereof can be exemplified.

In the present example, because the inner conductor 50C includes the wire assembly 53 including the plurality of resin wires 53 made of the first resin material and the first conductive layer 55C surrounding the wire assembly 53, similar to the first example, it is possible to reduce the rigidity of the coaxial cable 40C and it is possible to reduce reaction force of the coaxial cable 40C.

In the present example, because the reaction force of the coaxial cable 40C can be reduced as described above, similar to the first example, it is possible to suppress the occurrence of connection failures between the connectors 32 and 24, and it is possible to ensure sufficient connection reliability in the insertion and removal of the connectors 32 and 24 for several thousand times.

In the present example, because the inner conductor 50C includes the wire assembly 53 including the plurality of resin wires 53 made of the first resin material and the first conductive layer 55C surrounding the wire assembly 53, it is possible to suppress heat transfer from the chamber 111 of the handler 110 to the inside of the motherboard 30 and it is possible to suppress formation of dew condensation inside the motherboard 30.

In the present example, because the inner conductor 50C includes the wire assembly 53 including the plurality of resin wires 532 made of the first resin material and the first conductive layer 55C surrounding the wire assembly 53, it is possible to reduce the weight of several thousand to tens of thousands of coaxial cables 40C. Thus, it is possible to reduce the strength of the housing 31 holding the coaxial cable 40C, and it is possible to reduce the cost of the motherboard 30.

The configuration of the wire assembly 53 is not particularly limited to the above. Although the wire assembly 53 includes seven wires 532 in FIG. 5, the number of the wires constituting the wire assembly 53 is not particularly limited to this. For example, the wire assembly 53 may include 19 wires or may include 24 wires.

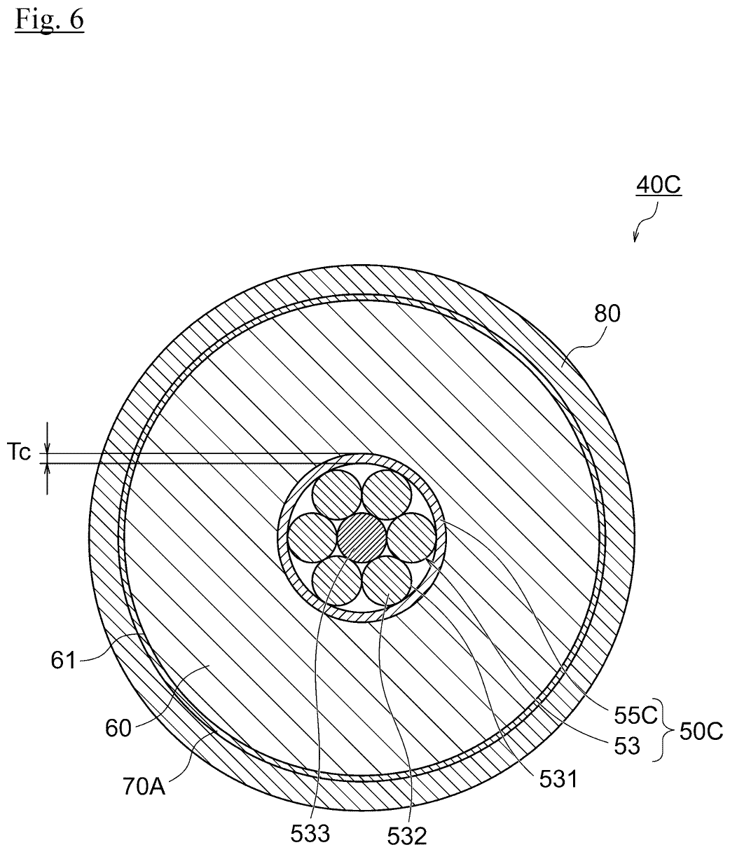

As shown in FIG. 6, the wire assembly 53 may include a first conductive wire 533 in addition to the resin wires 532. FIG. 6 is a sectional view showing a modification of the coaxial cable 40C in the third example.

In the modification shown in FIG. 6, the wire assembly 53 includes one first conductive wire 533 as its central wire, and six resin wires 532 are arranged to surround the first conductive wire 533. The first conductive wire 533 has a circular cross-sectional shape and is a solid linear member made of the second conductive material having good conductivity. The first conductive wire 533 is a linear member made of only the metal material. Although not particularly limited, for example, silver, copper, or alloys thereof can be exemplified as a specific example of the second metal material of which the first conductive wire 533 is made.

In the modification shown in FIG. 6, under the same measurement conditions, the first resin material of which the resin wire 532 is made has the Young's modulus (Era) smaller than the Young's modulus (Emb) of the second metal material of which the first conductive wire 533 is made (Era<Emb). Further, under the same measurement conditions, the first resin material has the thermal conductivity (λra) lower than the thermal conductivity (λmb) of the second metal material of which the first conductive wire 533 is made (λra<λmb). Furthermore, under the same measurement conditions, the first resin material has the density (ρra) lower than the density (ρmb) of the second metal material of which the first conductive wire 533 is made (ρra<ρmb).

Because the wire assembly 53 includes the first conductive wire 533, the coaxial cable 40C can also be used as a power supply line for supplying power to the DUT 200, and it is possible to enhance the versatility of the coaxial cable 40C.

The number of the first conductive wires 533 included in the wire assembly 53 is not particularly limited to the above as long as the wire assembly 53 includes at least one resin wire 532, and the wire assembly 53 may include a plurality of first conductive wires 533. The first conductive wire 533 may not be arranged at the center of the wire assembly 53, the first conductive wire 533 may be included in the wires surrounding the central wire, or the first conductive wire 533 may be included in the outermost wires of the wire assembly 53.

### Fourth Example

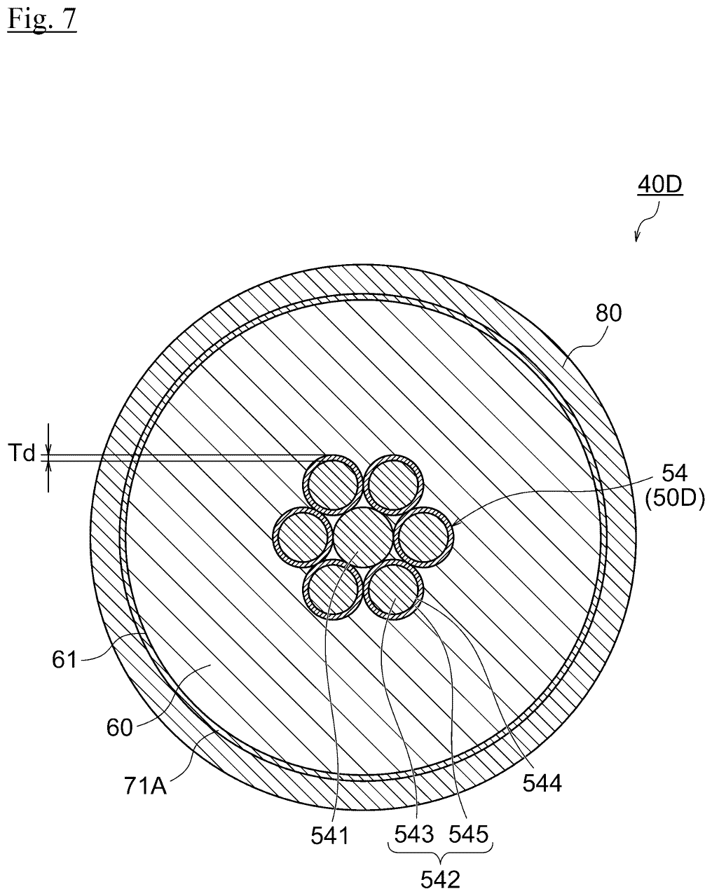

FIG. 7 is a sectional view showing the coaxial cable 40D in a fourth example of one or more embodiments. The present example is different from the first example in the configuration of the inner conductor 50D, but other configurations are the same as those of the first example. Hereinafter, the coaxial cable 40D in the fourth example will be described only with respect to differences from the first example, parts having the same configuration as those in the first example are denoted by the same reference numerals, and description thereof will be omitted.

As shown in FIG. 7, the inner conductor 50D of the present example includes a wire assembly 54 but does not include a first conductive layer that covers the outer peripheral surface of the wire assembly 54. The wire assembly 54 includes one inner wire 541 and a plurality of outer wires 542 arranged to surround the inner wire 541. The wire assembly 54 is a twisted wire formed by twisting a plurality of wires 541 and 542 together. The wire assembly 54 extends in the axial direction of the coaxial cable 40D.

The inner wire 541 has a circular cross-sectional shape and is a solid linear member made of a second resin material. The inner wire 541 is a linear member made of only the second resin material (a portion made of a resin material).

The outer wire 542 includes a first resin body 543 and a second conductive layer (portion made of a conductive material) 545 that covers the outer peripheral surface 544 of the first resin body 543. The first resin body 543 has a circular cross-sectional shape and is a solid linear member made of a third resin material. The first resin body 543 is a linear member made of only the third resin material. The second conductive layer 545 covers the entire outer peripheral surface 544 of the first resin body 543. The second conductive layer 545 covers the outer circumferential surface 544 of the first resin body 543 over the entire area in the axial direction of the coaxial cable 40D. Similar to the outer wire 542, the inner wire 541 may include a conductive layer that covers the outer peripheral surface of the resin body made of the second resin material.

The second conductive layer 545 is made of a third metal material. The second conductive layer 545 is a plated layer formed by a plating method. Although not particularly limited, the thickness Td of the thin film is, for example, preferably 0.1 μm or more and 20 μm or less (0.1 μm≤Td≤20 μm), and more preferably 0.1 μm or more and 10 μm or less (0.1 μm≤Td≤10 μm). Thus, it is possible to further reduce the rigidity of the coaxial cable 40D.

The second conductive layer 545 may be a thin film formed by a method other than plating such as physical vapor deposition (PVD) or chemical vapor deposition (CVD). Alternatively, the second conductive layer 545 may be a coating layer formed by applying a paint containing metal particles. Alternatively, the second conductive layer 545 may be formed of a metal foil instead of a thin film.

Under the same measurement conditions, the second resin material of which the inner wire 541 is made has the Young's modulus (Erb) smaller than the Young's modulus (Emc) of the third metal material of which the second conductive layer 545 is made (Erb<Emc). Further, under the same measurement conditions, the second resin material has the thermal conductivity (λrb) lower than the thermal conductivity (λmc) of the third metal material of which the second conductive layer 545 is made (λrb<λmc). Furthermore, under the same measurement conditions, the second resin material has the density (ρrb) lower than the density (ρmc) of the third metal material of which the second conductive layer 545 is made (ρrb<ρmc).

Similarly, under the same measurement conditions, the third resin material of which the first resin body 543 of the outer wire 542 is made has the Young's modulus (Erc) smaller than the Young's modulus (Emc) of the third metal material of which the second conductive layer 545 is made (Erc<Emc). Further, under the same measurement conditions, the third resin material has the thermal conductivity (λrc) lower than the thermal conductivity (λmc) of the third metal material of which the second conductive layer 545 is made (λrc<λmc). Furthermore, under the same measurement conditions, the third resin material has the density (ρrc) lower than the density (ρmc) of the third metal material of which the second conductive layer 545 is made (ρrc<ρmc).

Although a specific example of the second resin material of which the inner wire 541 is made are not particularly limited as long as it is a resin material having an electrically insulation property, for example, imide-based resin such as polyimide, fluororesin such as polytetrafluoroethylene (PTFE) and perfluoroalkoxy alkane (PFA), polyetheretherketone (PEEK), polyethylene (PE), and crosslinked foamed polyethylene can be exemplified. Similarly, although a specific example of the third resin material of which the first resin body 543 of the outer wire 542 is made are not particularly limited as long as it is a resin material having an electrically insulation property, for example, imide-based resin such as polyimide, fluororesin such as polytetrafluoroethylene (PTFE) and perfluoroalkoxy alkane (PFA), polyetheretherketone (PEEK), polyethylene (PE), and crosslinked foamed polyethylene can be exemplified. On the other hand, although a specific example of the third metal material of which the second conductive layer 545 is made is not particularly limited as long as it is a metal material having good conductivity, for example, silver, copper, or alloys thereof can be exemplified.

In the present example, because the inner conductor 50D includes the wire assembly 54 including the inner wire 541 made of a second resin material and the plurality of outer wires 542 arranged to surround the inner wire 541 and each of the outer wires 542 includes the first resin body 543 made of the third resin material and the second conductive layer 545 that covers the outer peripheral surface 544 of the first resin body 543, it is possible to reduce the rigidity of the coaxial cable 40D and it is possible to reduce reaction force of the coaxial cable 40D. That is, in the present example, focusing on the fact that the frequency of the electric signals used in the semiconductor device testing device is high frequency and the electrical signals concentrate on the surface part of the conductor as the frequency of the electric signals is higher due to the skin effect, the surface part of the inner conductor is made of the third conductive material, and the inner part of the inner conductor is made of the second and third resin materials, thus the reaction force of the coaxial cable 40D is reduced. Accordingly, it is possible to suppress the occurrence of disconnection when assembling the motherboard 30.

In the present example, because the reaction force of the coaxial cable 40D can be reduced as described above, similar to the first example, it is possible to suppress the occurrence of connection failures between the connectors 32 and 24, and it is possible to ensure sufficient connection reliability in the insertion and removal of the connectors 32 and 24 for several thousand times.

In the present example, because the inner conductor 50D includes the wire assembly 54 including the inner wire 541 made of a second resin material and the plurality of outer wires 542 arranged to surround the inner wire 541 and each of the outer wires 542 includes the first resin body 543 made of the third resin material and the second conductive layer 545 that covers the outer peripheral surface 544 of the first resin body 543, it is possible to suppress heat transfer from the chamber 111 of the handler 110 to the inside of the motherboard 30 and it is possible to suppress formation of dew condensation inside the motherboard 30.

In the present example, because the inner conductor 50D includes the wire assembly 54 including the inner wire 541 made of a second resin material and the plurality of outer wires 542 arranged to surround the inner wire 541 and each of the outer wires 542 includes the first resin body 543 made of the third resin material and the second conductive layer 545 that covers the outer peripheral surface 544 of the first resin body 543, it is possible to reduce the weight of several thousand to tens of thousands of coaxial cables 40D. Thus, it is possible to reduce the strength of the housing 31 holding the coaxial cable 40D, and it is possible to reduce the cost of the motherboard 30.

The configuration of the wire assembly 54 is not particularly limited to the above. Although the wire assembly 54 includes seven wires 541 and 542 in FIG. 7, the number of the wires constituting the wire assembly 54 is not particularly limited to this. For example, the wire assembly 54 may include 19 wires or may include 24 wires. In this case, as long as the outermost periphery of the wire assembly 54 is composed of the outer wires 542, either the inner wire 541 or the outer wire 542 may be used as the wire located inside the outermost periphery.

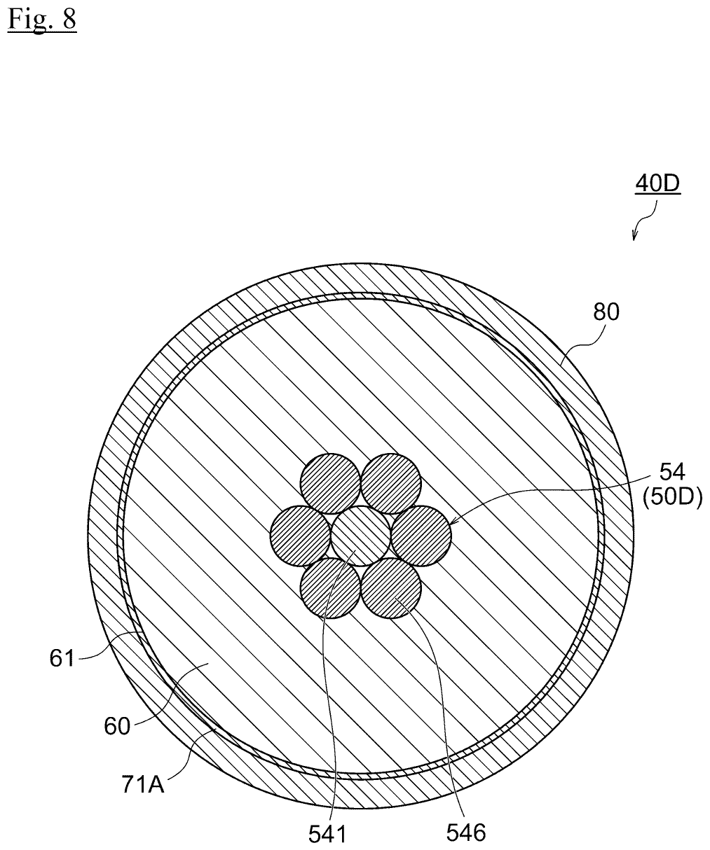

As shown in FIG. 8, instead of the outer wire 542, a second conductive wire 546 may be used as the outermost wire of the wire assembly 54. FIG. 8 is a sectional view showing a modification of the coaxial cable 40D in the fourth example.

In the modification shown in FIG. 8, the wire assembly 54 includes six second conductive wires 546 as the outermost wires, and the second conductive wires 546 are arranged to surround the inner wire 541. Each of the second conductive wires 546 has a circular cross-sectional shape and is a solid linear member made of the third conductive material having good conductivity. Each of the second conductive wires 546 is a linear member made of only the metal material. Although not particularly limited, for example, silver, copper, or alloys thereof can be exemplified as a specific example of the third metal material of which the second conductive wires 546 is made.

Because the wire assembly 54 includes the second conductive wire 546, the coaxial cable 40D can also be used as a power supply line for supplying power to the DUT 200, and it is possible to enhance the versatility of the coaxial cable 40D.

As long as the outermost periphery of the wire assembly 54 is composed of the second conductive wires 546, the inner wire 541 and the second conductive wire 546 can be arbitrarily arranged in the wire assembly 54. As the outermost wire of the wire assembly 54, the outer wire 542 and the second conductive wire 546 may be mixed.

### Fifth Example

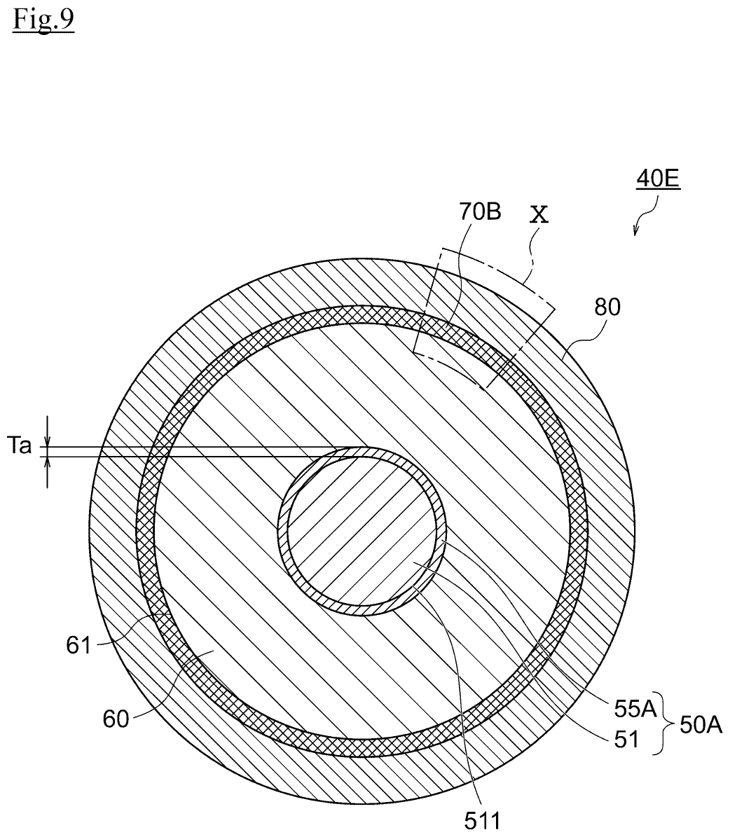

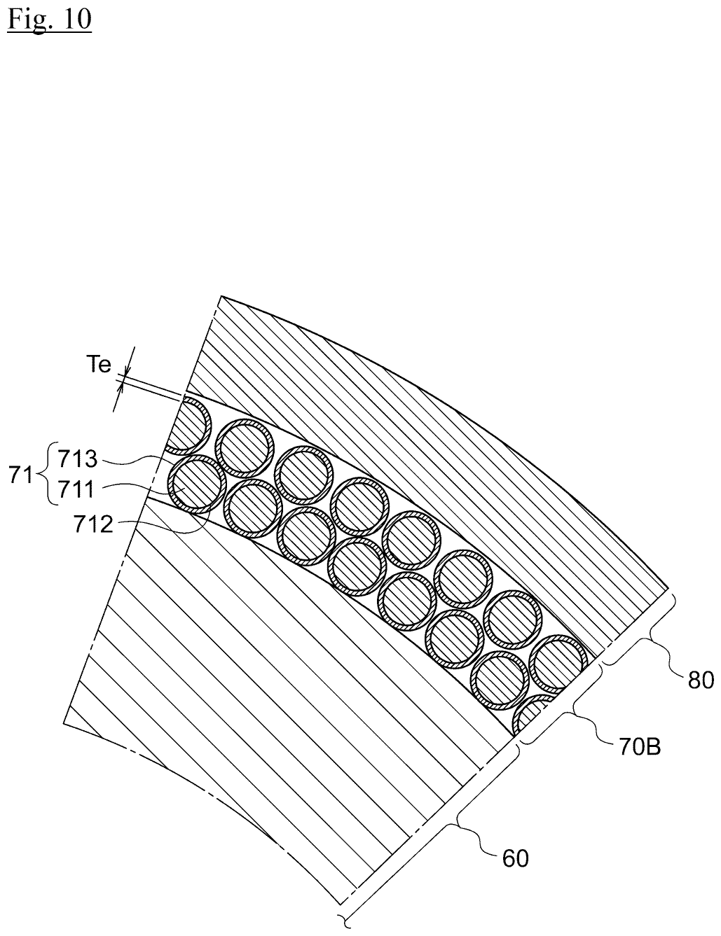

FIG. 9 is a sectional view showing the coaxial cable 40E in a fifth example of one or more embodiments, and FIG. 10 is an enlarged view of the section X in FIG. 9. As shown in FIG. 9, the present example is different from the first example in the configuration of the outer conductor 70B, but other configurations are the same as those of the first example. Hereinafter, the coaxial cable 40E in the fifth example will be described only with respect to differences from the first example, parts having the same configuration as those in the first example are denoted by the same reference numerals, and description thereof will be omitted.

The outer conductor 70B of the present example is a braided shield including a plurality of coated wires 71 that are braided. As shown in FIG. 10, each of the coated wires 71 includes a second resin body 711 and a third conductive layer 713 that covers the outer circumferential surface 712 of the second resin body 711. The second resin body 711 has a circular cross-sectional shape. The second resin body 711 is a solid linear member made of the fourth resin material. The second resin body 711 is a linear member made only of the fourth resin material. The third conductive layer 713 covers the entire circumference of the outer peripheral surface 712 of the second resin body 711. The third conductive layer 713 covers the outer circumferential surface 712 of the second resin body 711 over the entire area in the axial direction of the coaxial cable 40E.

The third conductive layer 713 is made of a fourth metal material. The third conductive layer 713 is a plated layer formed by a plating method. Although not particularly limited, the thickness Te of the thin film is, for example, preferably 0.1 μm or more and 20 μm or less (0.1 μm≤Te≤20 μm), and more preferably 0.1 μm or more and 10 μm or less (0.1 μm≤Te≤10 μm). Thus, it is possible to further reduce the rigidity of the coaxial cable 40E.

The third conductive layer 713 may be a thin film formed by a method other than plating such as physical vapor deposition (PVD) or chemical vapor deposition (CVD). Alternatively, the third conductive layer 713 may be a coating layer formed by applying a paint containing metal particles. Alternatively, the third conductive layer 713 may be formed of a metal foil instead of a thin film.

Under the same measurement conditions, the fourth resin material of which the second resin body 711 is made has the Young's modulus (Erd) smaller than the Young's modulus (Emd) of the fourth metal material of which the third conductive layer 713 is made (Erd<Emd). Further, under the same measurement conditions, the fourth resin material has the thermal conductivity (λrd) lower than the thermal conductivity (λmd) of the fourth metal material of which the third conductive layer 713 is made (λrd<λmd). Furthermore, under the same measurement conditions, the fourth resin material has the density (ρrd) lower than the density (ρmd) of the fourth metal material of which the third conductive layer 713 is made (ρrd<ρmd).

Although a specific example of the fourth resin material of which the second resin body 711 is made are not particularly limited as long as it is a resin material having an electrically insulation property, for example, imide-based resin such as polyimide, fluororesin such as polytetrafluoroethylene (PTFE) and perfluoroalkoxy alkane (PFA), polyetheretherketone (PEEK), polyethylene (PE), and crosslinked foamed polyethylene can be exemplified. On the other hand, a specific example of the fourth metal material of which the third conductive layer 713 is made is not particularly limited as long as it is a metal material having good conductivity, but for example, silver, copper, or alloys thereof can be exemplified.

In the present example, similar to the first example, because the inner conductor 50A includes the base member 51 made of the first resin material and the first conductive layer 55A surrounding the base member 51, it is possible to reduce the rigidity of the coaxial cable 40E and it is possible to reduce reaction force of the coaxial cable 40E. Accordingly, it is possible to suppress the occurrence of disconnection when assembling the motherboard 30.

In the present example, because the reaction force of the coaxial cable 40E can be reduced as described above, similar to the first example, it is possible to suppress the occurrence of connection failures between the connectors 32 and 24, and it is possible to ensure sufficient connection reliability in the insertion and removal of the connectors 32 and 24 for several thousand times.

In the present example, similar to the first example, because the inner conductor 50A includes the base member 51 made of the first resin material and the first conductive layer 55A surrounding the base member 51, it is possible to suppress heat transfer from the chamber 111 of the handler 110 to the inside of the motherboard 30 and it is possible to suppress formation of dew condensation inside the motherboard 30.

In the present example, similar to the first example, because the inner conductor 50A includes the base member 51 made of the first resin material and the first conductive layer 55A surrounding the base member 51, it is possible to reduce the weight of several thousand to tens of thousands of coaxial cables 40E. Thus, it is possible to reduce the strength of the housing 31 holding the coaxial cable 40E, and it is possible to reduce the cost of the motherboard 30.

In the present example, because the outer conductor 70B is the braided shield in which the plurality of coated wires 71 are braided and each of the coated wires 71 includes the second resin body 711 made of the fourth resin material and the third conductive layer 713 surrounding the second resin body 711, it is possible to further reduce the rigidity of the coaxial cable 40E and it is possible to further reduce reaction force of the coaxial cable 40E.

In the present example, because the outer conductor 70B is the braided shield in which the plurality of coated wires 71 are braided and each of the coated wires 71 includes the second resin body 711 made of the fourth resin material and the third conductive layer 713 surrounding the second resin body 711, it is possible to further suppress heat transfer from the chamber 111 of the handler 110 to the inside of the motherboard 30.

In the present example, because the outer conductor 70B is the braided shield in which the plurality of coated wires 71 are braided and each of the coated wires 71 includes the second resin body 711 made of the fourth resin material and the third conductive layer 713 surrounding the second resin body 711, it is possible to further reduce the weight of several thousand to tens of thousands of coaxial cables 40E.

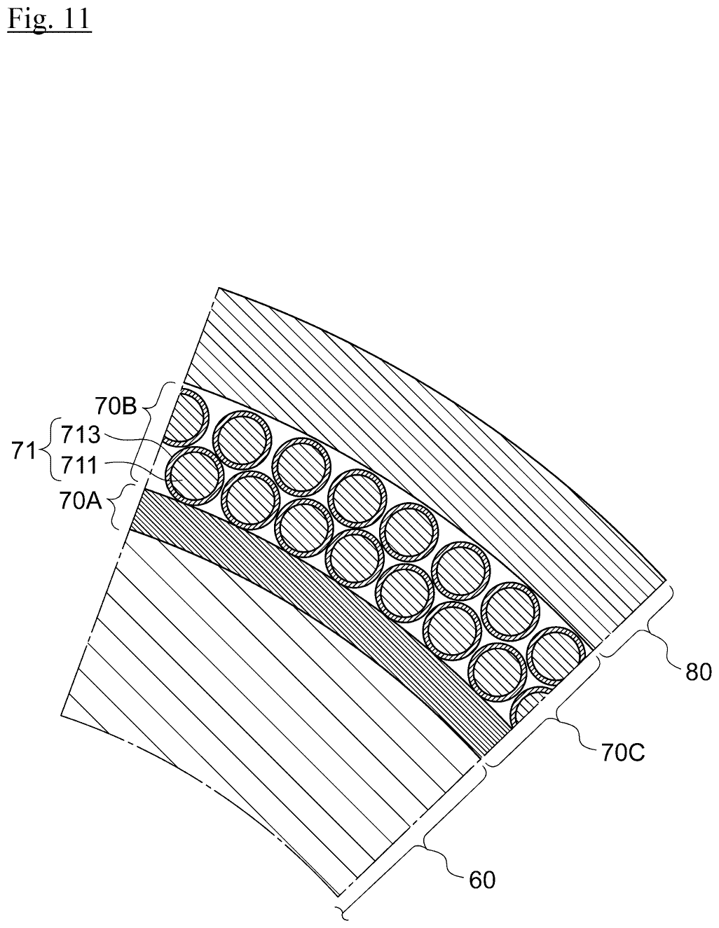

As shown in FIG. 11, the outer conductor 70C may include the thin film 70A described in the first example in addition to the above-described braided shield 70B. In this case, the braided shield 70B is arranged radially outside the thin film 70A. FIG. 11 is an enlarged sectional view showing a modification of the coaxial cable 40E in the fifth example and is a diagram showing a part corresponding to FIG. 10. In the modification shown in FIG. 11, the above-mentioned metal foil or metal pipe may be used instead of the thin film 70A.

Although the disclosure has been described with respect to only a limited number of embodiments, those skilled in the art, having benefit of this disclosure, will appreciate that various other embodiments may be devised without departing from the scope of the present disclosure. Accordingly, the scope of the disclosure should be limited only by the attached claims.

For example, the outer conductor 70B shown in FIG. 10 described in the fifth example may be applied to the coaxial cables 40B to 40D of the second to fourth examples. The outer conductor 70C shown in FIG. 11 may be applied to the coaxial cables 40B to 40D of the second to fourth examples.

### EXPLANATIONS OF LETTERS OR NUMERALS

1 . . . Semiconductor device testing apparatus
10 . . . Tester
20 . . . DSA
21 . . . Socket
22 . . . Contactor
24 . . . Coaxial connector
30 . . . Mother board
31 . . . Housing
32 . . . Coaxial connector
40A to 40E . . . Coaxial cable
50A to 50D . . . Inner conductor
51 . . . Base member (central part, portion made of resin material)
511 . . . Outer peripheral surface
52 . . . Cavity (central part)
53 . . . Wire assembly
531 . . . Outer peripheral surface
532 . . . Resin wire
533 . . . First conductive wire
54 . . . Wire assembly
541 . . . Inner wire
542 . . . Outer wire
543 . . . First resin body
544 . . . Outer peripheral surface
545 . . . Second conductive layer
546 . . . Second conductive wire
55A to 55C . . . First conductive layer
60 . . . Insulator
61 . . . Outer peripheral surface
62 . . . Inner hole
63 . . . Inner peripheral surface
70A . . . Outer conductor (Thin film)
70B . . . Outer conductor (Braided shield)
70C . . . Outer conductor
71 . . . Coated wire
711 . . . Second resin body
712 . . . Outer peripheral surface
713 . . . Third conductive layer (additional conductive layer)
80 . . . Jacket
90 . . . Test head
91 . . . Test module
92 . . . Cable
100 . . . Main frame
110 . . . Handler
111 . . . Chamber
112 . . . Opening
200 . . . DUT
210 . . . Terminal

What is claimed is:

1. A coaxial cable comprising:
an inner conductor comprising a central part and a conductive layer surrounding the central part;
an insulator surrounding the inner conductor; and
an outer conductor surrounding the insulator, wherein
the central part comprises either a cavity or a portion made of resin material.

2. The coaxial cable according to claim 1, wherein the conductive layer includes a thin film or a metal foil.

3. The coaxial cable according to claim 1, wherein the conductive layer has a thickness equal to or less than 20 μm.

4. The coaxial cable according to claim 1, wherein
the central part comprises a base member made of the resin material, and
the conductive layer covers an outer peripheral surface of the base member.

5. The coaxial cable according to claim 4, wherein a ratio of a cross-sectional area of the base member to a cross-sectional area of the inner conductor is equal to or more than 50%.

6. The coaxial cable according to claim 1, wherein
the central part comprises the cavity, and
the conductive layer covers an inner peripheral surface of the insulator.

7. The coaxial cable according to claim 6, wherein a ratio of a cross-sectional area of the cavity to a cross-sectional area of the inner conductor is equal to or more than 50%.

8. The coaxial cable according to claim 1, wherein
a wire assembly in the cavity comprises one or more resin wires made of the resin material,
the conductive layer covers an outer peripheral surface of the wire assembly.

9. The coaxial cable according to claim 8, wherein a ratio of a cross-sectional area of the one or more resin wires to a cross-sectional area of the inner conductor is equal to or more than 50%.

10. The coaxial cable according to claim 8, wherein the wire assembly further comprises a conductive wire.

11. A coaxial cable comprising:
an inner conductor;
an insulator surrounding the inner conductor; and
an outer conductor surrounding the insulator, wherein
the inner conductor comprises a wire assembly comprising:
an inner wire comprising a portion made of a resin material; and
outer wires surrounding the inner wire and each comprising a portion made of a conductive material.

12. The coaxial cable according to claim 11, wherein one of the outer wires comprises:
a resin body; and
a conductive layer covering an outer peripheral surface of the resin body.

13. The coaxial cable according to claim 12, wherein the conductive layer includes a thin film or a metal foil.

14. The coaxial cable according to claim 12, wherein the conductive layer has a thickness equal to or less than 20 μm.

15. The coaxial cable according to claim 11, wherein the outer wires include a conductive wire.

16. The coaxial cable according to claim 1, wherein
the outer conductor comprises a braided shield comprising coated wires that are braided,
one of the coated wires comprises:
a resin body; and
an additional conductive layer covering an outer peripheral surface of the resin body.

17. The coaxial cable according to claim 11, wherein
the outer conductor comprises a braided shield comprising coated wires that are braided,
one of the coated wires comprises:
a resin body; and
a conductive layer covering an outer peripheral surface of the resin body.

18. The coaxial cable according to claim 16, wherein the additional conductive layer includes a thin film or a metal foil.

19. The coaxial cable according to claim 16, wherein the additional conductive layer has a thickness equal to or less than 20 μm.

20. The coaxial cable according to claim 1, wherein the outer conductor comprises a conducting layer covering an outer peripheral surface of the insulator.

21. The coaxial cable according to claim 20, wherein the conducting layer includes a thin film or a metal foil.

22. A semiconductor device testing apparatus that tests a semiconductor device, comprising:
the coaxial cable according to claim 1.

23. A semiconductor device testing apparatus that tests a semiconductor device, comprising:
the coaxial cable according to claim 11.
